(19) United States
(12) Patent Application Publication
(10) Pub. No.: US 2008/0171425 A1
(43) Pub. Date: Jul. 17, 2008

(54) METHODS OF FORMING AN EPITAXIAL LAYER ON A GROUP IV SEMICONDUCTOR SUBSTRATE

(76) Inventors: Dmitry Poplavskyy, San Jose, CA (US); Maxim Kelman, Mountain View, CA (US); Francesco Lemmi, Sunnyvale, CA (US); Andreas Meisel, Redwood City, CA (US)

Correspondence Address: Foley & Lardner LLP, 150 East Gilman Street, Madison, WI, 53701-1497, US

(21) Appl. No.: 11/954,784

(22) Filed: Dec. 12, 2007

Related U.S. Application Data
(60) Provisional application No. 60/874,873, filed on Dec. 13, 2006.

(51) Int. Cl. H01L 21/36

(52) U.S. Cl. 438/509; 257/E21.461

(57) ABSTRACT

A method of forming an epitaxial layer in a chamber is disclosed. The method includes positioning a Group IV semiconductor substrate in the chamber; and depositing a nanoparticle ink, the nanoparticle ink including a set of Group IV nanoparticles and a solvent, wherein a porous compact is formed. The method also includes heating the porous compact to a temperature of between about 100° C. and about 1100° C., and for a time period of between about 5 minutes to about 60 minutes with a heating apparatus, wherein the epitaxial layer is formed.

### CROSS-REFERENCE TO RELATED APPLICATIONS

This application claims the benefit of U.S. Pat. App. No. 60/874,873 entitled EPITAXIAL THIN FILM FABRICATION FROM GROUP IV SEMICONDUCTOR NANOPARTICLES ON NATIVE GROUP IV SEMICONDUCTOR SUBSTRATES, filed Dec. 13, 2006, which is incorporated by reference.

### FIELD OF DISCLOSURE

The present invention relates in general to Group IV semiconductor manufacturing methods and in particular to methods of forming an epitaxial layer on a Group IV semiconductor substrate.

### BACKGROUND

Epitaxy is often the only practical method of high crystalline quality growth for many semiconductor materials, including technologically important materials as silicon-germanium, gallium nitride, gallium arsenide and indium phosphide. An epitaxy is generally a type of interface between a thin film and a substrate and generally describes an ordered crystalline growth on a monocrystalline substrate.

Generally grown from gaseous or liquid precursors, an epitaxial film or layer may be deposited such that its lattice structure and orientation matches that of the substrate lattice. This is substantially different from other thin-film deposition methods which deposit polycrystalline or amorphous films, even on single-crystal substrates. However, currently epitaxial techniques also tend to be costly, since expensive capital equipment must be utilized, such as chemical vapor deposition (CVD), vapor-phase epitaxy (VPE), molecular-beam epitaxy (MBE), and liquid-phase epitaxy (LPE).

Consequently, it would be beneficial to use less costly techniques in order to deposit an epitaxial layer on a substrate.

### SUMMARY

The invention relates, in one embodiment, to a method of forming an epitaxial layer in a chamber is disclosed. The method includes positioning a Group IV semiconductor substrate in the chamber; and depositing a nanoparticle ink, the nanoparticle ink including a set of Group IV nanoparticles and a solvent, wherein a porous compact is formed. The method also includes heating the porous compact to a temperature of between about 100° C. and about 1100° C., and for a time period of between about 5 minutes to about 60 minutes with a heating apparatus, wherein the epitaxial layer is formed.

The invention relates, in another embodiment, to a method of forming an epitaxial layer in a chamber. The method includes positioning a Group IV semiconductor substrate in the chamber; and depositing a nanoparticle ink, the nanoparticle ink including a set of Group IV nanoparticles and a solvent, wherein a porous compact is formed. The method also includes heating the substrate to a temperature of at least 250° C.; and heating the porous compact with a set of laser pulses from a laser apparatus, wherein each laser pulse of the set of laser pulses has a pulse duration, and a fluence; wherein the epitaxial layer is formed.

### BRIEF DESCRIPTION OF THE DRAWINGS

FIGS. 1A-1C show a schematic of embodiments of epitaxially grown thin films from native Group IV semiconductor substrates using Group IV semiconductor nanoparticles.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and or structures have not been described in detail in order to not unnecessarily obscure the present invention.

While not wishing to be bound by theory, it is believed by the inventor herein a thin film formed from a set of Group IV nanoparticles suspended in an ink may be used to form an epitaxial layer on a native Group IV substrate in a less costly manner than traditional deposition techniques.

### Characteristics of Group IV Nanoparticles

A Group IV semiconductor nanoparticle generally refers to hydrogen terminated nanoparticle having an average diameter between about 1.0 nm to 100.0 nm, and composed of silicon, germanium, and alpha-tin, or combinations thereof.

With respect to shape, embodiments of Group IV semiconductor nanoparticles include elongated particle shapes, such as nanowires, or irregular shapes, in addition to more regular shapes, such as spherical, hexagonal, and cubic nanoparticles, and mixtures thereof. Additionally, the nanoparticles may be single-crystalline, polycrystalline, or amorphous in nature. As such, a variety of types of Group IV semiconductor nanoparticle materials may be created by varying the attributes of composition, size, shape, and crystallinity of Group IV semiconductor nanoparticles. Exemplary types of Group IV semiconductor nanoparticle materials are yielded by variations including, but not limited by: 1) single or mixed elemental composition; including alloys, core/shell structures, doped nanoparticles, and combinations thereof; 2) single or mixed shapes and sizes, and combinations thereof; and 3) single form of crystallinity or a range or mixture of crystallinity, and combinations thereof.

In general, Group IV semiconductor nanoparticles have an intermediate size between individual atoms and macroscopic bulk solids. In some embodiments. Group IV semiconductor nanoparticles have a size on the order of the Bohr exciton radius (e.g., 4.9 nm), or the de Broglie wavelength, which allows individual Group IV semiconductor nanoparticles to trap individual or discrete numbers of charge carriers, either electrons or holes, or excitons, within the particle.

In addition, Group IV semiconductor nanoparticles may exhibit a number of unique electronic, magnetic, catalytic, physical, optoelectronic and optical properties due to quantum confinement and surface energy effects. For example, Group IV semiconductor nanoparticles exhibit luminescence effects that are significantly greater than, as well as melting temperatures of nanoparticles substantially lower than the complementary bulk Group IV materials. These unique effects vary with properties such as size and elemental composition of the nanoparticles.

For instance, the melting of germanium nanoparticles is significantly lower than the melting of silicon nanoparticles of comparable size. With respect to quantum confinement effects, for silicon nanoparticles, the range of nanoparticle dimensions for quantum confined behavior is between about 1 nm to about 15 nm, while for germanium nanoparticles, the range of nanoparticle dimensions for quantum confined behavior is between about 1 nm to about 35 nm, and for alpha-tin nanoparticles, the range of nanoparticle dimensions for quantum confined behavior is between about 1 nm to about 40 nm.

Regarding the terminology of the art for Group IV semiconductor thin film materials, the term “amorphous” is generally defined as non-crystalline material lacking long-range periodic ordering, while the term “polycrystalline” is generally defined as a material composed of crystallite grains, of different crystallographic orientation, where the amorphous state is either absent or minimized (e.g., within the grain boundary and having an atomic monolayer in thickness). With respect to the term “microcrystalline”, in some current definitions, this represents a thin film having properties between that of amorphous and polycrystalline, where the crystal volume fraction may range between a few percent to about 90%. In that regard, on the upper end of such a definition, there is arguably a continuum between that winch is microcrystalline and polycrystalline. In general, microcrystalline is a thin film in which crystallites are embedded in an amorphous matrix. In contrast, polycrystalline is a thin film in which crystallites are not constrained by crystallite size, but rather by a thin film having properties reflective of the highly crystalline nature.

In general, Group IV semiconductor nanoparticles may be made according to any suitable method, and in any suitable environment, such as an inert environment (e.g., argon, nitrogen, etc.), an ambient environment, or a vacuum environment. As used herein, “inert” is not limited to only substantially oxygen-free. For example, one plasma phase method, in which the particles are formed in an inert, substantially oxygen-free environment, is disclosed in U.S. patent application Ser. No. 11/155,340, filed Jun. 17, 2005; the entirety of which is incorporated herein by reference.

### Characteristics of Group IV Nanoparticle Inks

After the preparation of Group IV semiconductor nanoparticle materials is complete, the Group IV semiconductor nanoparticle materials may be transferred to polar solvent or solution for the preparation of embodiments dispersions and suspensions of the nanoparticles; or preparation of an ink. In general, the transfer may take place under vacuum or other inert environment. In terms of preparation of the dispersions, the use of particle dispersal methods such as sonication, high shear mixers, and high pressure/high shear homogenizers are contemplated for use to facilitate dispersion of the particles in a selected solvent or mixture of solvents.

Examples of solvents include alcohols, aldehydes, ketones, carboxylic acids, esters, amines, organosiloxanes, halogenated hydrocarbons, and other hydrocarbon solvents. In addition, the solvents may be mixed in order to optimize physical characteristics such as viscosity, density, polarity, etc.

In addition, in order to better disperse the Group IV nanoparticles in the colloidal dispersion or ink, nanoparticle capping groups may be formed with the addition of organic compounds, such as alcohols, aldehydes, ketones, carboxylic acids, esters, and amines, as well as organosiloxanes. Alternatively, capping groups may be added in-situ by the addition of gases into the plasma chamber. These capping groups may be subsequently removed during the sintering process, or in a lower temperature pre-heat just before the sintering process.

For example, bulky capping agents suitable for use in the preparation of capped Group IV semiconductor nanoparticles include C4-C8 branched alcohols, cyclic alcohols, aldehydes, and ketones, such as tertiary-butanol, isobutanol, cyclohexanol, methyl-cyclohexanol, butanal, isobutanal, cyclohexanone, and oraganosiloxanes, such as methoxy(tris(trimethylsilyl)silane)(MTTMSS), tris(trimethylsilyl)silane (TTMSS), decamethyltetrasiloxane (DMTS), and trimethylmethoxysilane (TMOS).

In addition, various embodiments of Group IV semiconductor nanoparticle Inks can be formulated by the selective blending of different types of Group IV semiconductor nanoparticles. For example, varying the packing density of Group IV semiconductor nanoparticles in a deposited thin layer is desirable for forming a variety of embodiments of Group IV photoconductive thin films. In that regard, Group IV semiconductor nanoparticle inks can be prepared in which various sizes of monodispersed Group IV semiconductor nanoparticles are specifically blended to a controlled level of polydispersity for a targeted nanoparticle packing. Further, Group IV semiconductor nanoparticle inks can be prepared in which various sizes, as well as shapes are blended in a controlled fashion to control the packing density.

Additionally, particle size and composition may impact fabrication processes, so that various embodiments of inks may be formulated that are specifically tailored to epitaxy fabrication. This is due to that fact that there is a direct con-elation between nanoparticle size and melting temperature. For example, for silicon nanoparticles between the size range of about 1 nm to about 15 nm, the melting temperature is in the range of between about 400° C. to about 1100° C. versus the melting of bulk silicon, which is 1420° C. For germanium, nanoparticles of in a comparable size range of about 1 nm to about 15 nm melt at a lower temperature of between about 100° C. to about 800° C., which is also significantly lower than the melting of bulk germanium at about 935° C. Therefore, the melting temperatures of the Group IV nanoparticle materials as a function of size and composition may be exploited in embodiments of ink formulations for targeting the fabrication temperature of a Group IV semiconductor epitaxial layer.

Alternatively, blended doped and undoped Group IV semiconductor nanoparticles inks may be formulated. For example, various embodiments of Group IV semiconductor nanoparticle inks can be prepared in which the dopant level for a specific thin layer of a targeted device design is formulated by blending doped and undoped Group IV semiconductor nanoparticles to achieve the requirements for that layer.

### Epitaxial Layer Formation

Once an appropriate ink has been formulated, a thin film of Group IV semiconductor nanoparticles may then be deposited on a native Group IV semiconductor substrate using a variety of techniques, as previously described in order to form an epitaxial layer.

Such a thin film, of Group IV semiconductor nanoparticles is referred to as a porous compact or green film. Forming the epitaxial layer may be done in an inert (e.g., argon, nitrogen, etc.), ambient, or vacuum environment, using temperatures between about 100° C. to about 1100° C., depending on the type of nanoparticles used (i.e. the size of the particle, and the composition).

Heat sources contemplated for use include conventional contact thermal sources, such as resistive heaters, as well as radiative heat sources, such as lasers, and microwave processing equipment. More specifically, lasers operating in the wavelength range of between 280 nm and about 1064 nm, and microwave processing equipment operating in even longer wavelength ranges are matched to the fabrication requirements of embodiments of Group IV semiconductor thin films described herein. These types of apparatuses have the wavelengths for the effective penetration the film thicknesses, as well as the power requirements for fabrication of such thin film devices.

Regarding the time required to fabricate a deposited Group IV nanoparticle thin film into an epitaxial layer, the time required varies as an inverse function in relation to the processing temperature. For example, in the case of rapid thermal processing (RTF), if the processing temperature is about 800° C., the processing time may be, for example, between about 5 minutes to about 15 minutes. However, if the processing temperature is about 400° C., then the processing temperature may be between about, for example, 1 hour to about 10 hours. The fabrication process may also optionally include the use of pressure of between up about 7000 psig. The process of preparing Group IV semiconductor thin films from Group IV semiconductor nanoparticle materials has been described in U.S. App, No. 60/842,818, with a filing date of Sep. 7, 2006, and entitled, “Semiconductor Thin Films Formed from Group IV Nanoparticles,” and incorporated by reference.

Alternatively, if a pulse laser is used to fabricate the epitaxial layer, a pulse duration range of between about 1 ns to about 100 ns, a repetition rate of between about 1 Hz and about 1000 Hz, and a fluence of between about 1 mJ/m² and about 200 mJ/m² may be used. If a continuous laser is used to form the epitaxial layer, a duration range of between about 1 see to about 10 sec, and a fluence of between about 1 mJ/m² and about 200 mJ/m² may be used.

Additionally, the Group IV semiconductor substrate may be preheated to at least 250° C. in order to assist the templating of the epitaxial layer. Templating refer to the process of forming an initial or seed epitaxial layer on the Group IV semiconductor substrate surface, and matching the lattice orientation of the Group IV semiconductor substrate.

The native Group IV semiconductor substrates contemplated for use with Group IV semiconductor nanoparticles include crystalline silicon wafers of a variety of orientations. For example, in some embodiments of epitaxially grown Group IV semiconductor thin films, wafers of silicon (100) are contemplated for use, while in other embodiments, wafers of silicon (111) are contemplated for use, and in still other embodiments, wafers of silicon (110) are contemplated for use.

Such crystalline substrate wafers may be doped with p-type dopants for example, such as boron, gallium, and aluminum. Alternatively, they may be doped with n-type dopants, for example such as arsenic, phosphorous, and antimony. If the crystalline silicon substrates are doped, the level of doping would ensure a bulk resistivity of up to about 100 ohm×cm. Other native silicon substrates contemplated include polycrystalline silicon substrates, such as, for example, those formed from PECVD, laser crystallization, or SSP processes. In addition to silicon, such substrates could also be made of germanium and alpha-tin, and combinations of silicon, germanium, and alpha-tin.

### EXAMPLE 1

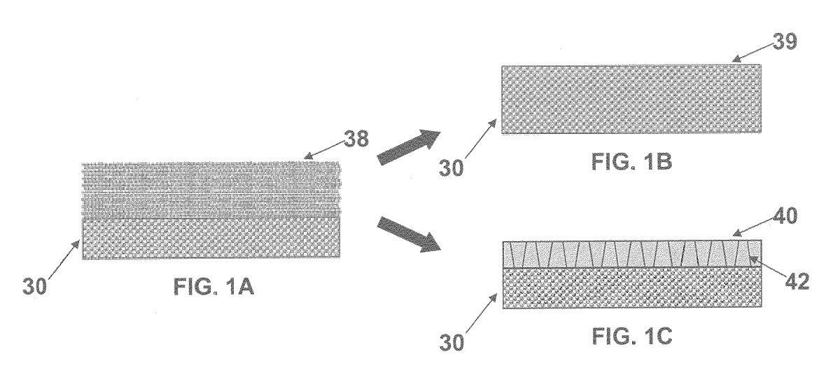

Referring now to FIG. 1A, a porous compact or green film 38 is shown deposited upon a native Group IV semiconductor substrate 30, having periodic spacings of atoms indicative of crystal line material.

Referring now to FIG. 1B, a first epitaxial crystalline film is shown. First, crystalline silicon nanoparticles of between about 1 nm to about 15 nm are deposited on a silicon wafer substrate to form a porous compact. Next, the porous compact is heated to a temperature between about 400° C. and about 1100° C., and for a period of between about 15 minutes to about 1 hr, in order to form an epitaxial crystalline film that cannot generally be distinguished from substrate 30.

Referring now to FIG. 1C, a second epitaxial crystalline film is shown. First, amorphous silicon nanoparticles of between about 1 ran to about 15 nm are deposited on a silicon wafer substrate to form a porous compact. Next, the porous compact is heated to a temperature between about 300° C. to about 800° C., and for a period of between about 1 hour to about 15 minutes, in order to form an epitaxial polycrystalline film that cannot generally be distinguished from substrate 30.

Here, the epitaxial layer formed 40 generally has grain boundaries 42 indicative of polycrystalline material, which is distinguished from the substrate 30. Consequently, a range of native Group IV semiconductor substrates from crystalline to polycrystalline may be used.

Additionally, any of the types of inks previously described could be used to form an epitaxial layer on a native Group IV semiconductor substrate. For example, in various configurations of epitaxial layers on native Group IV semiconductor substrates, p-type or n-type doped Group IV semiconductor nanoparticles may be used to form an epitaxial layer. In other configurations, formulations of inks having mixtures of particles with different melting profiles could be used to form an epitaxial layer. For example, germanium nanoparticles of between about 1 nm to about 15 nm, having a lower melting profile than silicon nanoparticles, may be mixed with silicon nanoparticles of the same size. Additionally, amorphous silicon nanoparticles of between about 1 nm to about 15 nm, having a lower melting profile than crystalline silicon nanoparticles nm may be mixed with crystalline silicon nanoparticles of between about 1 nm to about 15 nm.

### EXAMPLE 2

A 1″×1″×0.2″ silicon substrate was first doped with arsenic with a resistivity of about 0.005 ohm×cm, and then cleaned by treatment with concentrated hydrofluoric acid vapor for 2 minutes.

In addition, a silicon nanoparticle ink was prepared in an inert environment from the silicon nanoparticles of about 8.0 nm+/−0.5 nm as a 20 mg/ml solution of chloroform/chlorobenzene (4:1 v/v), which was sonicated using a sonication horn at 35% power for 15 minutes.

Alternatively, the inventor believes that other solvents may be used, such as C4-C8 branched alcohols, cyclic alcohols, aldehydes, and ketones, such as tertiary-butanol, isobutanol, cyclohexanol, methyl-cyclohexanol, butanal, isobutanal, cyclohexanone, and oraganosiloxanes.

Applying sufficient silicon nanoparticle ink to substantially cover the wafer surface, a silicon nanoparticle porous compact was formed using spin casting, at 700 rpm for 60 seconds.

After the formation of the silicon nanoparticle porous compact of about 1200 nm, an epitaxial layer was fabricated using a conditioning step of baking the porous compact at 1.00° C. for 4 hours m a nitrogen atmosphere, followed by thin film fabrication at 765° C. at a pressure of between about 10⁻⁴ Torr to about 10⁻⁷ Torr for about 6 minutes, after a 15 minute ramp to the targeted fabrication temperature. The epitaxial layer formed was about 300-350 nm. As was seen in a SEM cross-section, no difference was observed between the silicon substrate and the densified silicon thin film.

### EXAMPLE 3

In a TEM image, it was shown that an epitaxial layer may be formed from silicon nanoparticles on a silicon substrate at 765° C., which is significantly below the melting temperature of bulk silicon, which is about 1420° C.

### EXAMPLE 4

In a SEM image, it was shown that an epitaxial layer was formed from the deposition of a silicon nanoparticle ink as was used in Example 2 and Example 3, for deposition onto a 1″×1″×0.2″ silicon substrate, doped with arsenic and having a resistivity of about 0.005 ohm×cm.

Applying sufficient silicon nanoparticle ink to substantially cover the wafer surface, a silicon nanoparticle porous compact was formed using spin casting, at 1000 rpm for 60 seconds. A portion of the porous compact was subsequently removed from an edge portion of the silicon wafer, and the film thickness was measured with a profilometer to be about 700 nm.

Consequently, an epitaxial layer was subsequently formed. First, the porous compact was conditioned at 100° C. for 30 minutes in a nitrogen atmosphere. Next, the porous compact was further heated to a temperature of 1050° C. (at a fast ramp of about >10° C./sec) and at a pressure of between about 10⁻⁴ to about 10⁻⁷ Torr for 7 minutes. Consequently, a densified film formed was about 300-350 nm, showing no substantial difference between the silicon substrate and the densified silicon thin film.

Advantages of the invention include the ability to form an epitaxial layer on a Group IV substrate. An additional advantage includes the formation of the epitaxial layer in a less costly manner than traditional deposition techniques.

Having disclosed exemplary embodiments and the best mode, modifications and variations may be made to the disclosed embodiments while remaining within the subject and spirit of the invention as defined by the following claims.

1. A method of forming an epitaxial layer in a chamber, comprising:
positioning a Group IV semiconductor substrate in the chamber; depositing a nanoparticle ink, the nanoparticle ink including a set of Group IV
nanoparticles and a solvent, wherein a porous compact is formed;
heating the porous compact to a temperature of between about 100° C. and about 1100° C., and for a time period of between about 5 minutes to about 60 minutes with a heating apparatus;
wherein the epitaxial layer is formed.

2. The method of claim 1, wherein the set of Group IV nanoparticles comprises silicon, and wherein each of the set of Group IV nanoparticles has a diameter of between 1 nm and about 15 nm.

3. The method of claim 1, wherein the set of Group IV nanoparticles comprises germanium, and wherein each of the set of Group IV nanoparticles has a diameter of between 1 nm and about 35 nm.

4. The method of claim 1, wherein the set of Group IV nanoparticles comprises tin, and wherein each of the set of Group IV nanoparticles has a diameter of between 1 nm and about 40 nm.

5. The method of claim 1, wherein the Group IV semiconductor substrate is one of silicon (100), silicon (111), and silicon (110).

6. The method of claim 1, wherein the Group IV semiconductor substrate is
doped with at least one p-type dopant.

7. The method of claim 6, wherein the p-type dopant is one of boron, gallium, and aluminum.

8. The method of claim 1, wherein the Group IV semiconductor substrate is
doped with at least one n-type dopant.

9. The method of claim 6, wherein the n-type dopant is one of arsenic, phosphorous, and antimony.

10. The method of claim 1, wherein the heating apparatus is one of a resistive heat
source apparatus and a radiative heat source apparatus.

11. The method of claim 1, wherein the solvent is one of alcohols, aldehydes, ketones, carboxylic acids, esters, amines, organosiloxanes, and halogenated hydrocarbons.

12. The method of claim 1, wherein the chamber is configured with a vacuum environment, the vacuum environment having a pressure of between about 10⁻⁴ Torr and about 10⁻⁷ Torr.

13. The method of claim 1, wherein the chamber is configured with an inert environment, the inert environment having one of nitrogen and argon.

14. The method of claim 1, wherein the chamber is configured with an ambient environment.

15. A method of forming an epitaxial layer in a chamber, comprising:
positioning a Group IV semiconductor substrate in the chamber;
depositing a nanoparticle ink, the nanoparticle ink including a set of Group IV nanoparticles and a solvent, wherein a porous compact is formed;
heating the Group IV semiconductor substrate to a temperature of at least 250° C.;
heating the porous compact with a set of laser pulses from, a laser apparatus, wherein each laser pulse of the set of laser pulses has a pulse duration and a fluence;
wherein the epitaxial layer is formed.

16. The method of claim 15, wherein the laser apparatus has an emission of between about 280 nm and about 1064 nm.

17. The method of claim 15, wherein the set of laser pulses has a repetition rate of about 1 Hz and about 1000 Hz.

18. The method of claim 17, wherein the pulse duration is about 1 ns to about 100 ns.

19. The method of claim 15, wherein the pulse exposure is from about 1 sec and about 10 sec.

20. The method of claim 15, wherein the fluence is between about 1 mJ/m² and about 200 mJ/m²

21. The method of claim 15, wherein the set of Group IV nanoparticles comprises silicon, and wherein each of the set of Group IV nanoparticles has a diameter of between 1 nm and about 15 nm.

22. The method of claim 15, wherein the set of Group IV nanoparticles comprises germanium, and wherein each of the set of Group IV nanoparticles has a diameter of between 1 nm and about 35 nm.

23. The method of claim 15, wherein the set of Group IV nanoparticles comprises tin, and wherein each of the set of Group IV nanoparticles has a diameter of between 1 nm and about 40 nm.

24. The method of claim 15, wherein the Group IV semiconductor substrate is one of silicon (100), silicon (111), and silicon (110).

25. The method of claim 15, wherein the Group IV semiconductor substrate is doped with at least one p-type dopant.

26. The method of claim 25, wherein the p-type dopant is one of boron, gallium, and aluminum.

27. The method of claim 15, wherein the Group IV semiconductor substrate is doped with at least one n-type dopant.

28. The method of claim 27, wherein the n-type dopant is one of arsenic, phosphorous, and antimony.

29. The method of claim 15, wherein the heating apparatus is one of resistive heat source apparatus and a radiative heat source apparatus.

30. The method of claim 15, wherein the solvent is one of alcohols, aldehydes, ketones, carboxylic acids, esters, amines, organosiloxanes, and halogenated hydrocarbons.

31. The method of claim 15, wherein the chamber is configured with a vacuum environment, the vacuum environment having a pressure of between about 10⁻⁴ Torr and about 10⁻⁷ Torr.

32. The method of claim 15, wherein the chamber is configured with a inert environment, the inert environment having one of nitrogen and argon.

33. The method of claim 15, wherein the chamber is configured with an ambient environment.
